(19) United States
(12) Patent Application Publication
(10) Pub. No.: US 2025/0283938 A1
(43) Pub. Date: Sep. 11, 2025

(54) ANALOG ENVIRONMENTAL MONITORING CIRCUITS AND METHODS

(71) Applicant: Microsoft Technology Licensing, LLC, Redmond, WA (US)

(72) Inventors: Kenneth Colin DYER, Pleasanton, CA (US); Iskender AGI, Redwood City, CA (US)

(21) Appl. No.: 18/597,069

(22) Filed: Mar. 6, 2024

(51) Int. Cl. G01R 31/3161; G01R 31/28; G01R 31/30; G01R 31/317

(52) U.S. Cl. CPC G01R 31/3161; G01R 31/2839; G01R 31/3004; G01R 31/31727

(57) ABSTRACT

Embodiments of the present disclosure includes a margin measurement circuit to determine margin of one or more signal monitoring circuits. Signals corresponding to voltages, temperatures, or clock signals may monitor deviation above or below trip points. Faults are triggered if the signals deviate outside a range set by the trip points. Margin between actual signal trip points and the set high and low trip points of the monitoring circuits may be measured by a margin measurement circuit. In some embodiments, the set trip points may be optimized for particular electronic system operation conditions. The present techniques may improve an electronic system's ability to detect and prevent remote or local attacks.

### BACKGROUND

The present disclosure relates generally to semiconductor circuits, and in particular, to analog environmental monitoring circuits and methods.

Analog environmental monitoring circuits (“AEMC”) are circuits that monitor voltages, temperatures, and clock signals during chip operation. One application of AEMCs is to monitors circuit operating conditions to detect intruders attempting to defeat chip security systems by manipulating temperature, voltages, and clock signals, for example. An AEMC may send a signal to the Hardware Security Platform (HSP) when environmental stress is detected. For example, an AEMC may issue a signal when a temperature, voltage, or clock signal are manipulated, indicating that the electronic system is under attack.

It may be advantageous to test AEMC blocks while the system is operation. Additionally, AEMCs should not give false alarms. Accordingly, “margin,” how close the monitor is to tripping (e.g., in temperature, voltage, or codes) is important, particularly where different systems have different conditions from a chip test system and margin cannot be guaranteed by automated test environment (ATE) measurements alone.

The present disclosure is directed to circuits and methods that may be used as analog environmental monitor circuits.

### BRIEF DESCRIPTION OF THE DRAWINGS

FIG. 1 illustrates a circuit according to an embodiment.

FIG. 2 illustrates a method according to an embodiment.

FIG. 3 illustrates an example monitor circuit according to an embodiment.

FIG. 4 illustrates an example margin measurement circuit according to an embodiment.

FIG. 5 illustrates an example margin measurement circuit according to another embodiment.

FIG. 6 illustrates another example margin measurement circuit according to an embodiment.

FIG. 7 illustrates another example margin measurement circuit according to an embodiment.

FIG. 8A illustrates another example margin measurement circuit according to an embodiment.

FIG. 8B illustrates a waveform for a clock signal corresponding to FIG. 8A.

FIG. 9 illustrates a waveform for a clock signal according to an embodiment.

FIG. 10 illustrates another example margin measurement circuit according to an embodiment.

### DETAILED DESCRIPTION

Described herein are circuit techniques for analog environmental monitor circuits. In the following description, for purposes of explanation, numerous examples and specific details are set forth in order to provide a thorough understanding of some embodiments. Various embodiments as defined by the claims may include some or all of the features in these examples alone or in combination with other features described below and may further include modifications and equivalents of the features and concepts described herein.

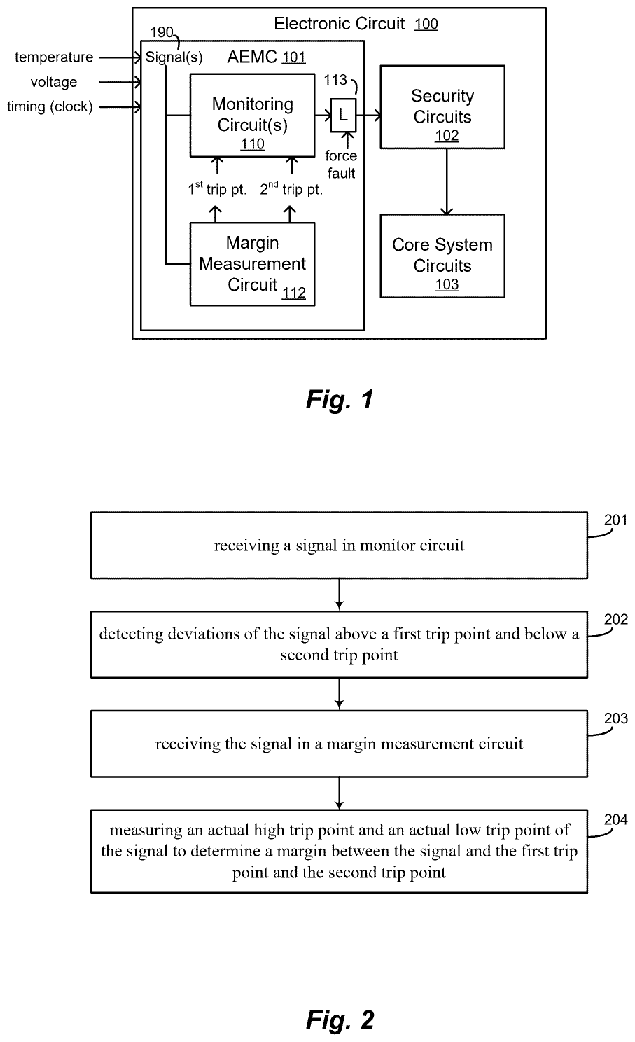

FIG. 1 illustrates a circuit according to an embodiment. Features and advantages of the present disclosure include techniques for improved monitoring of electronic system operating conditions, which may be used to prevent undesirable system attacks, for example. In FIG. 1, an electronic circuit 100 includes an analog environmental monitor circuit (AEMC) 101. AEMC 101 may comprise one or more monitor circuits 110 to monitor a variety of operational conditions, such as temperature, voltage (e.g., power supply voltage), or one or more timing signals (e.g., clock signals), for example. AEMC 101 may generate one or more fault signals to the hardware security system (e.g., security circuits 102) in response to deviations of one or more of temperature, voltage, and timing outside normal operating conditions. If security circuits 102 received a fault signal, they may turn off or otherwise inactivate some or all of core system circuits 103, for example. Core system circuits 103 may include, for example, digital circuits such as one or more processors (e.g., CPU, GPU, AI processors or the like) or a system on a chip. Electronic circuit 101 may be a single integrated circuit, for example. The present techniques can also be used for chiplets and multi-chip systems. An AEMC may exist in one or more die/chiplet in the system, for example.

In some cases, an attacker may cause a timing violation by putting the voltage, temperature, or clock out of specification for the cell library used for digital logic. The logic may be verified over temperature and voltage ranges, outside of those it may be vulnerable to environmental attack. In certain embodiments, an AEMC is designed to work outside the range of the digital timing. The purpose of the AEMC may include protecting the system from environmental conditions in which a timing violation may occur. This includes setup, hold violations and bit flips. An attacker may subject the device to electromagnetic interference, disturbing the digital circuitry by flipping logic into bad states. The clock monitor would trip if the clock pattern is disturbed by an attack of that nature. One challenge with testing AEMC 101 is that it is generally undesirable to change certain operational conditions outside the expected operating ranges. For example, increasing temperature, supply voltage, or clock speed (e.g., during testing) may cause damage to the electronic circuit. In some embodiments, AEMC 101 may include a logic circuit 113 to force one or more of the fault signals when the temperature, voltage, and timing are not deviating outside normal operating conditions. For example, a user may write a positive bit (‘1’) to a register and the value may be output on a fault signal to indicate to security circuits 102 that a fault has occurred (e.g., even though none of the operational conditions are outside their nominal ranges). In one embodiment, the logic circuit 113 comprises one or more AND gates having one input couple to a monitor circuit output carrying a trigger signal and a second input coupled to an override signal. When the override signal is 1, the AND gates output the monitor circuit output. When the override signal is 0, the AND gate output (e.g., the fault signal to security circuits 102) is forced to 0, which may indicate a fault. Accordingly, it may be determined how electronic circuit 100 responds to faults without having to modify the operating conditions of the circuit and potentially damaging the circuit, for example.

In this example, circuit 100 includes one or more monitor circuits 110 configured to receive corresponding one or more signals 190. Signals 190 may be one or more power supply voltages, one or more voltages corresponding to temperature, or one or more clock signals, for example. Monitor circuits 110 detect deviations of signals 190 above one or more first trip points (1^{st} trip pt.) and below one or more second trip points (2^{nd} trip pt.). Circuit 100 further includes at least one margin measurement circuit 112 configured to receive signals 190. Margin measurement circuit 112 measure one or more actual high trip points and one or more actual low trip points of signals. For instance, signals 190 may have a certain amount of noise (e.g., voltage noise, jitter noise, or phase noise). Accordingly, trip points above and below a particular signal may previously have needed to be set with sufficient margin (e.g., above and below the nominal signal value) such that the noise would not cause false triggers. Additionally, exact values of the signals may vary slightly across different applications (e.g., circuit boards or environments). Accordingly, trip points above and below a particular signal may previously have needed to be set with sufficient margin such that the variations across applications would not cause false triggers. However, unnecessarily wide trip points may leave the system exposed to potential attacks. Margin measurement circuit 112 advantageously determines margin between signals 190 and the trip points by measuring actual high trip points and actual low trip points of the signal to determine margin. An actual high trip point may be a voltage (or phase/phase code) of a signal above the nominal voltage (or phase/phase code) where the signal may deviate (e.g., and cause a trigger due to noise). An actual low trip point may be a voltage (or phase/phase code) of a signal below the nominal voltage (or phase/phase code) where the signal may deviate (e.g., and cause a trigger due to noise). Example measurements of actual trip points are illustrated below. In some embodiments, the trip points used to detect deviations of the signals 190 may be adjusted based on the measured margin to optimize the performance of the system.

FIG. 2 illustrates a method according to an embodiment. At 201, one or more signals are received in corresponding one or more monitor circuits. At 202, deviations of the one or more signals above corresponding one or more first trip points and below corresponding one or more second trip points are detected. At 203, the one or more signals are received in a measurement circuit. At 204, one or more actual high trip points and one or more actual low trip points of one or more signals are measured to determine margin between the one or more signals and the one or more first trip points and the one or more second trip points.

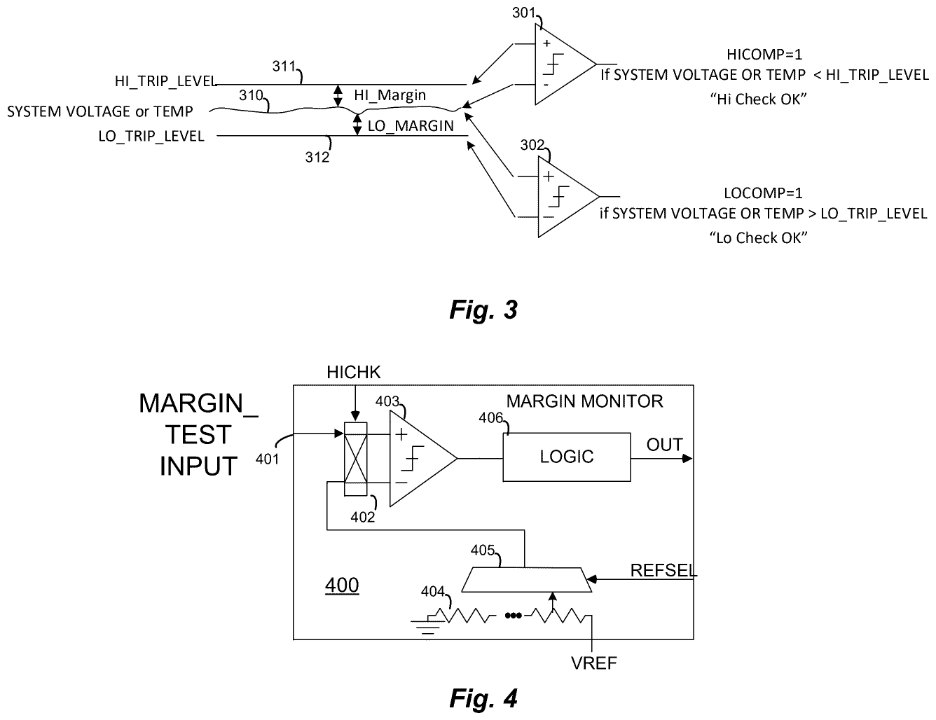

FIG. 3 illustrates an example monitor circuit according to an embodiment. In this example, one or more monitor circuits comprise a first comparator 301 and a second comparator 302 configured to produce one or more trigger signals (HICOMP, LOCOMP) in response to deviation of a voltage signal 310 (e.g., a system voltage or voltage generated from a temperature, e.g., using a PN junction) above a first trip point 311 (HI_TRIP_LEVEL) and below a second trip point 312 (LO_TRIP_LEVEL). In this example configuration of comparators, the first comparator 301 comprises a first input (+) coupled to a first trip point voltage 311 and a second input (−) coupled to signal 310. Comparator 301 generates a first trigger signal (HICOMP) in response to a voltage of signal 310 being above the first trip point voltage 311. Similarly, comparator 302 comprises a first input (+) coupled to signal 310 and a second input (−) coupled to a second trip point voltage (LO_TRIP_LEVEL). Comparator 302 generates a second trigger signal (LOCOMP) in response to the voltage of signal 310 being below the second trip point voltage. In this example convention, HICOMP=1 and LOCOMP=1 when signal 310 is between trip points 311 and 312. When signal 310 increases above trip point 311 or decreases below trip point 312, one of HICOMP or LOCOMP go to 0, triggering a fault, for example. Here, margin is the voltage range allowed for noise and drift (e.g., from temperature or age) in the system. In other words, margin may indicate how close a voltage or temperature is to HI/LO trip level measured in voltage or temperature. Further, it may be undesirable to measure actual HI_MARGIN or actual LO_MARGIN without stopping system.

FIG. 4 illustrates an example margin measurement circuit according to an embodiment. In this example, margin measurement circuit 400 comprising a comparator 403 having a first input 401 selectively coupled to one or more signals (e.g., signal 310, FIG. 3) and a second input of comparator 403 is coupled to an adjustable reference voltage. In this example embodiment, the margin measurement circuit 400 comprises a resistor divider 303 comprising a plurality of taps having a plurality of voltages and a multiplexer (MUX) 405 configured to select one of the plurality of voltages to produce the adjustable reference voltage. A plurality of monitor circuits that monitor different signals may be coupled to the input 401 of margin measurement circuit 400 to measure margin of each circuit. For instance, a signal may be coupled to input 401. Margin measurement circuit 400 includes a switch circuit 402 to selectively couple input 401 to either the + or − input of comparator 403. First, the signal may be coupled to the + input and the adjustable reference voltage is coupled to the − input using the HICHK control signal. The adjustable reference voltage may initially be configured below a low trip point 312, for example, by programming bits of the MUX control input REFSEL. Next, the REFSEL bits are changed to incrementally increase the adjustable reference voltage until the output of the comparator 403 switches state. REFSEL may be used to determine the corresponding actual trip voltage where the comparator switched on the low side. Similarly, the signal on input 401 may be coupled to the − input and the adjustable reference voltage is coupled to the + input. The adjustable reference voltage may initially be configured above a high trip point 311, for example, by programming bits of the MUX control input REFSEL. Next, the REFSEL bits are changed to incrementally decrease the adjustable reference voltage until the output of the comparator 403 switches state. REFSEL may be used to determine the corresponding actual trip voltage where the comparator switched on the high side. HI_margin and LO_margin may then be calculated. Trip levels may be adjusted to optimize margin to particular conditions of each signal in a plurality of different monitor circuits measuring multiple system voltages and/or temperatures, for example. Margin measurement circuit 400 may operate concurrently with monitor circuits, a plurality of which may be configured in an array on a semiconductor chip, for example.

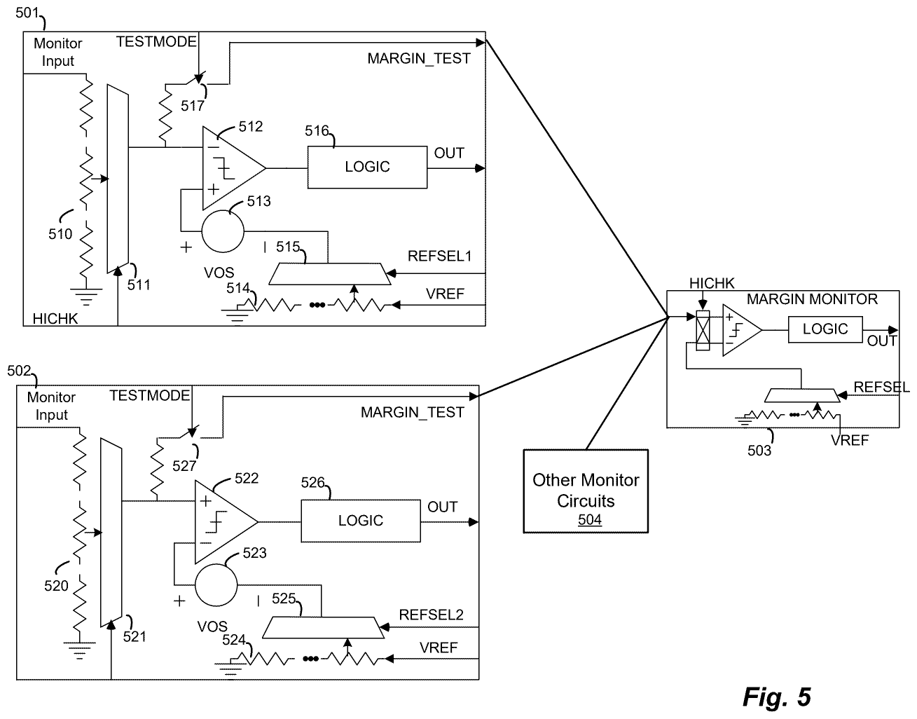

FIG. 5 illustrates an example margin measurement circuit according to another embodiment. In this example, the circuit includes switches 517/527 coupled between an input of the monitor circuits 501/502 and an input of the margin measurement circuit 503 to selectively couple signals to an input of the margin measurement circuit. Additional monitor circuits 504 may similarly be coupled to a single margin measurement circuit 503, for example. This example illustrates that a plurality of monitor circuits and a plurality of different signals (e.g., voltages, temperatures) may be separately coupled to an input of the margin measurement circuit 503 to determine margins between corresponding actual high trip points of the signals and set/configured high trip points in different monitor circuits and margins between actual low trip points and set/configured low trip points in different monitor circuits. In this example, the same signal is received in both monitor circuits 501-502. The signal may be coupled through resistor dividers 510/520, multiplexers 511/521 (e.g., programmable gain adjustment), and switches 517/527, to − and + inputs of comparators 512/522, respectively. For example, a TESTMODE lines may be use to individually select each module to be tested to the margin measurement circuit 503. Here, high and low trip points are set by multi-tap resistor dividers 514/524, MUXs 515/525 (e.g., including a second programmable gain adjustment) using REFSEL1 and REFSEL2 MUX control inputs, respectively. Offset voltages 513 and 513 may be calibrated and included in the circuit model. During manufacturing and/or during operation in an application, switches 517 and 527 may be periodically closed to couple the monitored signal to margin measurement circuit 503. Margin measurement circuit 503 may measure actual margin and adjust the reference voltages by changing REFSEL1 and/or REFSEL2 to optimize the high and low trip points for better system performance.

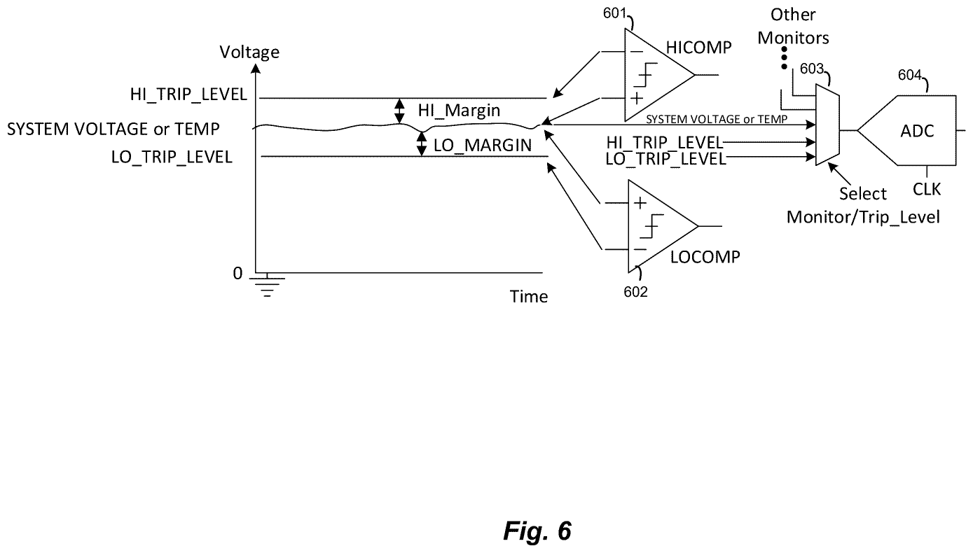

FIG. 6 illustrates another example margin measurement circuit according to an embodiment. In this example, the margin measurement circuit includes an analog multiplexer 603 having a first input coupled to monitor signals and additional inputs coupled to the set high and low trip points (HI_TRIP_LEVEL and LO_TRIP_LEVEL) of comparators (e.g., comparators 601/602) of a plurality of monitor circuits. Further in this example, margin measurement circuit is an analog-to-digital converter (ADC) 604 selectively coupled to the one or more signals (e.g., through one or more MUXs 603). A select input of MUX 603 may be configured to couple signals and trip points to ADC 604. In this example, the system may execute an algorithm that samples the signals and set high/low trip levels and determines margin digitally, for example.

In one embodiment, a process of determining margin may be as follows. First, the system calibrates ADC Gain and Offset for each monitor, including the margin test circuit. Next, the system selects HI trip and records the ADC code=Hi_Trip_Code (e.g., measure HI trip point average). Next, the system selects Lo Trip and records ADC Code=Lo_Trip_Code (e.g., measure LO trip point average). The system then selects signal input and record ADC Code=Monitor_Code (e.g., measure the signal average). Margin are calculated as follows:

Hi Margin=Hi_Trip_Code-Monitor_Code

Lo Margin=Monitor_Code-Lo_Trip_code

If the comparator offset calibration is available for the trip comparators (e.g., from a test system), the margin levels may be adjusted based on tester measured ADC offset, for example, as follows:

Hi_Margin_Corrected=Hi Margin−Hi_Comp Offset

Lo_Margin_Corrected=Lo Margin+Lo_Comp Offset

Once one monitor is completed, the next monitor may be selected and the process repeated across all monitors.

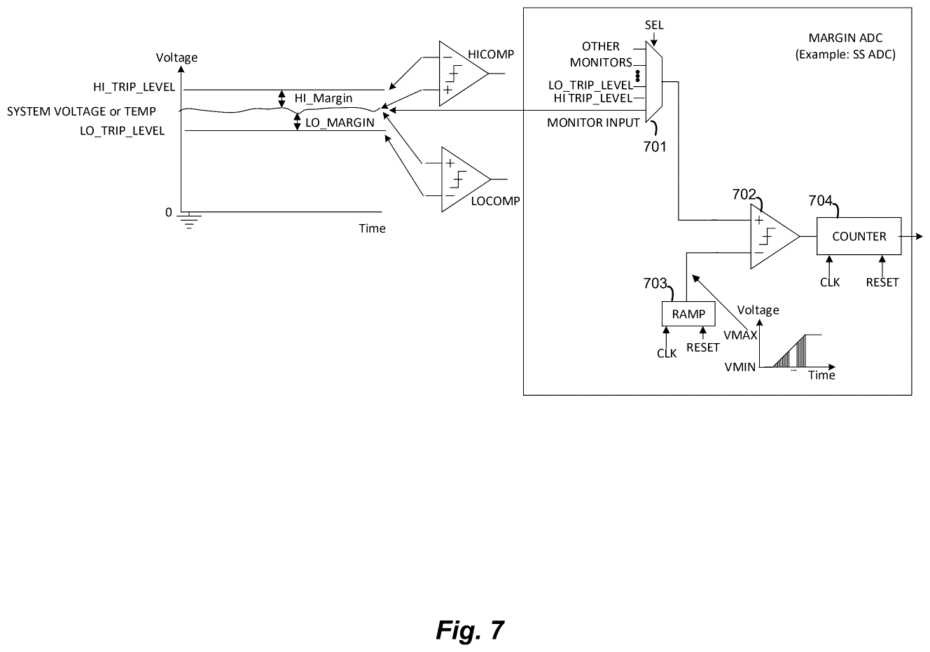

FIG. 7 illustrates another example margin measurement circuit according to an embodiment. In this example, a margin measurement circuit comprises a ramp generator 703 to produce the adjustable reference voltage. For example, MUX 701 may successively couple signals and configured HI/LO trip levels to an input of comparator 702. Ramp generator 703 may receive a clock and reset input, for example. Ramp generator 703 may increase the reference voltage until the comparator trips. A counter 704 is used in this example to convert voltage to a digital trip value. After each measurement, the ramp and counter may be reset, for example. Accordingly, the voltage may be swept in steps from VMAX to VMIN to calibrate a monitored voltage or temperature signal and determine actual high and low trip points. As mentioned above, comparator 702 may be reused for multiple monitor circuits for different signals, where the margin measurement circuits may measure margin during normal operation of the monitor circuits without tripping the monitor circuits, for example. The ramp generator shown in FIG. 7 may constitute a single slope analog-to-digital converter (ADC). The ADC can be made of elements of the AEMC (e.g., FIG. 7) or with another ADC such as a Flash, successive approximation register (SAR), Sigma-Delta, pipeline, or similar architechtures for the ADC shown in FIG. 6.

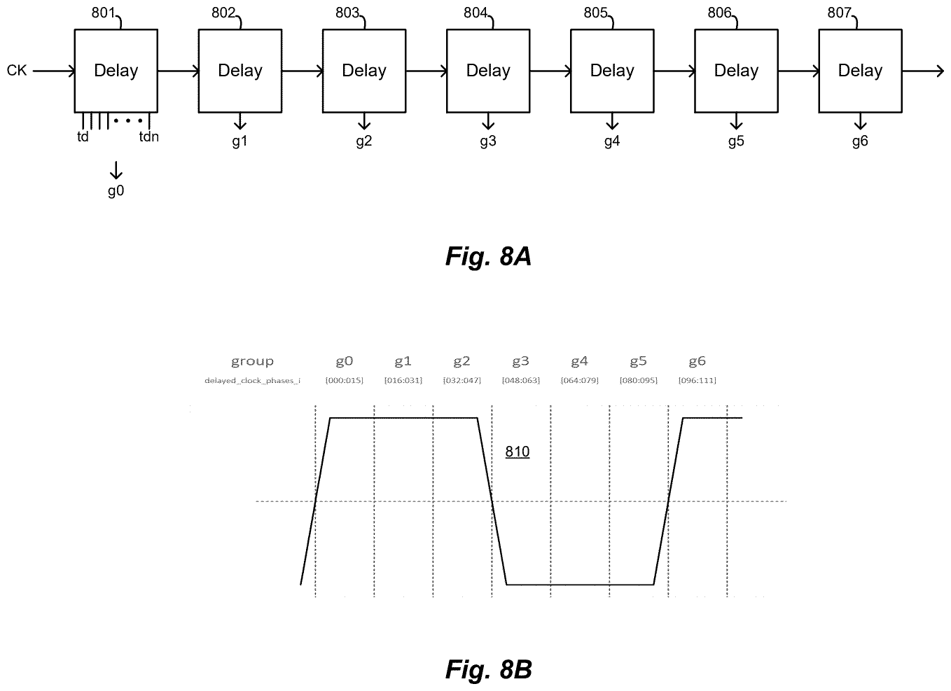

FIG. 8A illustrates another example margin measurement circuit according to an embodiment. In this example, a margin measurement circuit includes a plurality of delay circuits 801-807 configured in series to receive a clock signal (CK) and generate a plurality of delayed clock signals (e.g., td−tdn). Delay circuits 801-807 include a plurality of taps forming a plurality of codes. A logic circuit may be configured to measure margin of an edge of the clock signal based on the plurality of codes, for example. In this example, the taps are divided into seven (7) groups, g0-g6 (e.g., 16 taps each producing 7 16-bit codes). FIG. 8B illustrates a timing diagram 810 for FIG. 8A. FIG. 8B illustrates a snapshot of a clock signal. At a particular moment in time, the clock waveform produces corresponding code values. Due to imperfections in the clock such as duty cycle distortion and systematic jitter, code values around transitions incorrect or unstable. Such values are labeled as underdetermined (“x”). For instance, g0 code values may comprise initial undetermined values, x, during the transition followed by 1's. All 16 bits for g1 may be 1, and g2 may be a series of 1's ending with undetermined values, x, during the transition. The number of undetermined values, x, around a transition may be due to noise, for example. These codes may be used to guard-band the timing of the clock signal, for example.

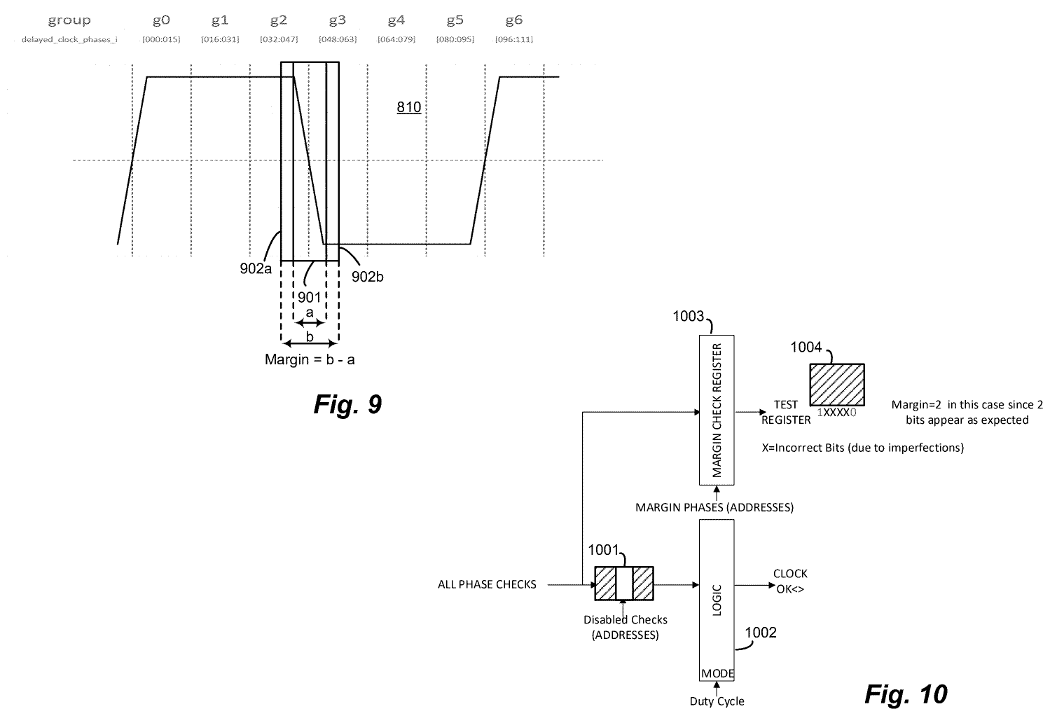

FIG. 9 illustrates the waveform 810 for a clock signal according to an embodiment. In this example, bits in the region 901 may be undetermined. A high trip point 902a may be defined such that if the clock frequency increases such that edge occurs before point 902a (e.g., the code value of g2 has too many trailing x's and not enough leading 1's and g3 has too few x's and/or too many trailing 0's), then a fault may be triggered. Similarly, a low trip point 902b may be defined such that if the clock frequency decreases such that edge occurs after point 902b (e.g., the code value of g2 has too many leading 1's and not enough trailing x's and/or g3 has too few leading x's and too many trailing 0's), then a fault may be triggered. One of ordinary skill in the art will also see that the codes may be used to determine margin by counting bits across regions “a” 901 and “b” between 902a-b in FIG. 9, where margin may be equal to the time between the high and low trip points, b, subtracted from the time corresponding to the undetermined values during the transition, a.

FIG. 10 illustrates another example margin measurement circuit according to an embodiment. In this example, the codes are masked at 1001 and coupled to a logic circuit 1002. The mask 1001 may disable undetermined values, x, and input the 1s and 0s to logic circuit 1002. Logic circuit 1002 is configured to evaluate the codes to determine if the timing of the clock edge has transitioned above the high trip point or below the low trip point. If not, the output of logic circuit 1002 indicates the clock is okay. However, if the edge deviates outside the high or low trip points, a fault condition is generated. A margin check circuit 1003 receive unmasked bits, determine the actual high trip point and actual low trip point (e.g., where the x's begin and end on either side of a transition), and determine margin. The determined margin for each timing signal being measure using the techniques described above may be used to customize the high and low trip points used to detect faults, for example.

### Further Examples

Each of the following non-limiting features in the following examples may stand on its own or may be combined in various permutations or combinations with one or more of the other features in the examples below. Embodiments of the present disclosure may include systems, circuits, and methods.

In one embodiment, the present disclosure includes a circuit comprising: one or more monitor circuits configured to receive corresponding one or more signals, the one or more monitor circuits detecting deviations of the one or more signals above one or more first trip points and below one or more second trip points; and at least one margin measurement circuit configured to receive the one or more signals, the margin measurement circuit measuring one or more actual high trip points and one or more actual low trip points of the one or more signals to determine one or more margins between the one or more signals and the one or more first trip points and the one or more second trip points.

In one embodiment, the one or more monitor circuits comprising: a first comparator and a second comparator configured to produce one or more trigger signals in response to said deviations of the one or more signals above the one or more first trip points and below the one or more second trip points.

In one embodiment, the first comparator comprises a first input coupled to a first trip point voltage and a second input coupled to a first signal of the one or more signals, the first comparator generating a first trigger signal of said one or more trigger signals in response to a voltage of the first signal being above the first trip point voltage; and the second comparator comprises a first input coupled to the first signal and a second input coupled to a second trip point voltage, the second comparator generating a second trigger signal of said one or more trigger signals in response to the voltage of the first signal being below the second trip point voltage.

In one embodiment, the margin measurement circuit comprising a comparator having a first input selectively coupled to the one or more signals, a second input coupled to an adjustable reference voltage.

In one embodiment, the margin measurement circuit comprising: a resistor divider comprising a plurality of taps having a plurality of voltages; and a multiplexer configured to select one of the plurality of voltages to produce the adjustable reference voltage.

In one embodiment, the margin measurement circuit comprising a ramp generator to produce the adjustable reference voltage.

In one embodiment, margin measurement circuit comprising a single slope analog-to-digital converter.

In one embodiment, the one or more signals are a plurality of signals, the margin measurement circuit comprising an analog multiplexer having a first input coupled to the plurality of signals.

In one embodiment, the margin measurement circuit comprising an analog-to-digital converter selectively coupled to the one or more signals.

In one embodiment, the margin measurement circuit comprising: a plurality of delay circuits configured in series to receive a clock signal and generate a plurality of delayed clock signals, the delay circuits comprising a plurality of taps forming a plurality of codes; and logic circuit configured to measure margin of an edge of the clock signal based on the plurality of codes.

In one embodiment, the present disclosure further comprises one or more switches coupled between an input of the one or more monitor circuits and an input of the margin measurement circuit to selectively couple the one or more signals to an input of the margin measurement circuit.

In one embodiment, the one or more monitor circuits are a plurality of monitor circuits and the one or more signals are a plurality of signals, and wherein the plurality of signals are separately coupled to an input of the margin measurement circuit to determine first margins between corresponding actual high trip points and first trip points and second margins between actual low trip points and second trip points.

In one embodiment, one or more of the first trip points and the second trip points are adjusted based on the margin.

In one embodiment, at least one of the one or more signals is a power supply voltage.

In one embodiment, at least one of the one or more signals is a voltage corresponding to a temperature.

In one embodiment, at least one of the one or more signals is a clock signal.

In one embodiment, the circuit comprises one or more processors or a system on a chip.

In one embodiment, the present disclosure includes a method of measuring margin comprising: receiving one or more signals in corresponding one or more monitor circuits; detecting deviations of the one or more signals above corresponding one or more first trip points and below corresponding one or more second trip points; receiving the one or more signals in a measurement circuit; and measuring one or more actual high trip points and one or more actual low trip points of one or more signals to determine margin between the one or more signals and the one or more first trip points and the one or more second trip points.

In one embodiment, the present disclosure includes a circuit comprising: digital circuitry, a hardware security system; and an analog environmental monitor circuit configured to generate one or more fault signals to the hardware security system in response to deviations of one or more of temperature, voltage, and timing outside normal operating conditions, the analog environmental monitor circuit comprising a logic circuit to force one or more of the fault signals when the temperature, voltage, and timing are not deviating outside normal operating conditions.

The above description illustrates various embodiments along with examples of how aspects of some embodiments may be implemented. The above examples and embodiments should not be deemed to be the only embodiments, and are presented to illustrate the flexibility and advantages of some embodiments as defined by the following claims. Based on the above disclosure and the following claims, other arrangements, embodiments, implementations, and equivalents may be employed without departing from the scope hereof as defined by the claims.

What is claimed is:

1. A circuit comprising:
one or more monitor circuits configured to receive corresponding one or more signals, the one or more monitor circuits detecting deviations of the one or more signals above one or more first trip points and below one or more second trip points; and
at least one margin measurement circuit configured to receive the one or more signals, the margin measurement circuit measuring one or more actual high trip points and one or more actual low trip points of the one or more signals to determine one or more margins between the one or more signals and the one or more first trip points and the one or more second trip points.

2. The circuit of claim 1, the one or more monitor circuits comprising:
a first comparator and a second comparator configured to produce one or more trigger signals in response to said deviations of the one or more signals above the one or more first trip points and below the one or more second trip points.

3. The circuit of claim 2, wherein:
the first comparator comprises a first input coupled to a first trip point voltage and a second input coupled to a first signal of the one or more signals, the first comparator generating a first trigger signal of said one or more trigger signals in response to a voltage of the first signal being above the first trip point voltage; and
the second comparator comprises a first input coupled to the first signal and a second input coupled to a second trip point voltage, the second comparator generating a second trigger signal of said one or more trigger signals in response to the voltage of the first signal being below the second trip point voltage.

4. The circuit of claim 1, the margin measurement circuit comprising a comparator having a first input selectively coupled to the one or more signals, a second input coupled to an adjustable reference voltage.

5. The circuit of claim 4, the margin measurement circuit comprising:
a resistor divider comprising a plurality of taps having a plurality of voltages; and
a multiplexer configured to select one of the plurality of voltages to produce the adjustable reference voltage.

6. The circuit of claim 4, the margin measurement circuit comprising a ramp generator to produce the adjustable reference voltage.

7. The circuit of claim 1, wherein margin measurement circuit comprising a single slope analog-to-digital converter.

8. The circuit of claim 1, wherein the one or more signals are a plurality of signals, the margin measurement circuit comprising an analog multiplexer having a first input coupled to the plurality of signals.

9. The circuit of claim 1, the margin measurement circuit comprising an analog-to-digital converter selectively coupled to the one or more signals.

10. The circuit of claim 1, the margin measurement circuit comprising:
a plurality of delay circuits configured in series to receive a clock signal and generate a plurality of delayed clock signals, the delay circuits comprising a plurality of taps forming a plurality of codes; and
logic circuit configured to measure margin of an edge of the clock signal based on the plurality of codes.

11. The circuit of claim 1, further comprising one or more switches coupled between an input of the one or more monitor circuits and an input of the margin measurement circuit to selectively couple the one or more signals to an input of the margin measurement circuit.

12. The circuit of claim 1, wherein the one or more monitor circuits are a plurality of monitor circuits and the one or more signals are a plurality of signals, and wherein the plurality of signals are separately coupled to an input of the margin measurement circuit to determine first margins between corresponding actual high trip points and first trip points and second margins between actual low trip points and second trip points.

13. The circuit of claim 1, wherein one or more of the first trip points and the second trip points are adjusted based on the margin.

14. The circuit of claim 1, wherein at least one of the one or more signals is a power supply voltage.

15. The circuit of claim 1, wherein at least one of the one or more signals is a voltage corresponding to a temperature.

16. The circuit of claim 1, wherein at least one of the one or more signals is a clock signal.

17. The circuit of claim 1, wherein the circuit comprises one or more processors or a system on a chip.

18. A method of measuring margin comprising:
receiving one or more signals in corresponding one or more monitor circuits;
detecting deviations of the one or more signals above corresponding one or more first trip points and below corresponding one or more second trip points;
receiving the one or more signals in a measurement circuit; and
measuring one or more actual high trip points and one or more actual low trip points of one or more signals to determine margin between the one or more signals and the one or more first trip points and the one or more second trip points.

19. The method of claim 18, further comprising adjusting one or more of the first trip point and the second trip point based on the margin.

20. A circuit comprising:
digital circuitry,
a hardware security system; and
an analog environmental monitor circuit configured to generate one or more fault signals to the hardware security system in response to deviations of one or more of temperature, voltage, and timing outside normal operating conditions, the analog environmental monitor circuit comprising a logic circuit to force one or more of the fault signals when the temperature, voltage, and timing are not deviating outside normal operating conditions.
